(19) United States
(12) Patent Application Publication
(10) Pub. No.: US 2025/0311364 A1
(43) Pub. Date: Oct. 2, 2025

(54) HIGH ELECTRON MOBILITY SEMICONDUCTOR DEVICE

(71) Applicant: SK keyfoundry Inc., Cheongju-si (KR)

(72) Inventor: Soo Chang KANG, Seoul (KR)

(73) Assignee: SK keyfoundry Inc., Cheongju-si (KR)

(21) Appl. No.: 18/932,068

(22) Filed: Oct. 30, 2024

(30) Foreign Application Priority Data
Apr. 2, 2024 (KR) 10-2024-0044718

(51) Int. Cl. H01L 29/423; H01L 23/31; H01L 29/20; H01L 29/40; H01L 29/778

(52) U.S. Cl. CPC H10D 64/411; H01L 23/3171; H01L 23/3192; H10D 30/475; H10D 62/8503; H10D 64/111

(57) ABSTRACT

A high electron mobility semiconductor device includes a substrate; a buffer layer on the substrate; a channel layer on the buffer layer; a barrier layer on the channel layer; a step-shaped P-type gallium nitride (P-GaN) on the barrier layer; a source metal and a drain metal formed on the left and right sides of the P-GaN region; and a gate metal on the step-shaped P-GaN region.

### CROSS-REFERENCE TO RELATED APPLICATION

This application claims the benefit under 35 U.S.C. § 119(a) of Korean Patent Application No. 10-2024-0044718, filed on Apr. 2, 2024, the entire disclosure of which is incorporated herein by reference for all purposes.

### BACKGROUND

### 1. Field

The following description relates to a high electron mobility semiconductor device, and more particularly, to a high electron mobility transistor (HEMT) device.

### 2. Discussion of Related Art

The statements in this section merely provide background information related to the present disclosure and do not necessarily constitute prior art.

As an alternative to overcome the limitations of silicon (Si)-based semiconductor devices, semiconductor devices fabricated based on other materials have been proposed. Gallium nitride (GaN)-based semiconductor devices are one example of such semiconductor devices. GaN-based semiconductor devices offer potential advantages for use in high-power applications due to the wide band gap of GaN.

FIG. 1 illustrates a cross-sectional view of a GaN-based semiconductor device. As shown in FIG. 1, a semiconductor device 1 includes a substrate 2, a buffer layer 3, and a channel layer 4. The channel layer 4 is formed of GaN. On top of the channel layer, which is the GaN layer 4, an aluminum gallium nitride (AlGaN) layer 5 and a passivation layer 11 are stacked in order.

A two-dimensional electron gas (2-DEG) layer 13 is naturally formed between the AlGaN layer 5 and the GaN layer 4. To control the flow of electrons from the source region 9 to the drain region 10, a gate structure 6 is formed on top of the AlGaN layer 5. The gate structure 6 generally includes a P-type doped gallium nitride (P-GaN) region 8 having a high work function and a gate metal 7 disposed on the P-GaN region 8. When the gate structure 6 includes the P-GaN region 8, the 2-DEG formed as a channel layer under the P-GaN region 8 is removed and is in a normally off state. When a positive voltage is applied to the gate metal 7, a channel layer is formed under the P-GaN region 8, allowing the device to operate.

In such a structure, when a voltage is applied to the gate metal 7, current flows downward through the gate metal 7 and a leakage current is generated through a vulnerable portion of the surface of the P-GaN region 8. This leakage current causes damage to the P-GaN region 8. Damage to the P-GaN region 8 affects the uniformity of the threshold voltage and the reliability of the semiconductor device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes: a substrate; a buffer layer on the substrate; a channel layer on the buffer layer; a barrier layer on the channel layer; a step-shaped P-type gallium nitride (P-GaN) region on the barrier layer; a source metal and a drain metal formed on left and right sides of the P-GaN region; and a gate metal on the step-shaped P-GaN region.

The step-shaped P-GaN region may be formed to extend further in a direction towards the drain metal than in a direction towards the source metal.

The step-shaped P-GaN region may have a greater number of step shapes in the direction towards the drain metal.

The gate metal may include an upper region and a lower region. The upper region may be formed with a first width. The lower region may be formed with the first width, and a second width and a third width smaller than the first width.

The step-shaped P-GaN region may not be in contact with the lower region. A first length formed towards the source metal may be not in contact with the lower region and may be shorter than a second length formed towards the drain metal.

The second width may be smaller than the third width, and the second width may be formed closer to the source metal.

In the lower region, a first region and a second region with different areas may be formed in a zigzag pattern, and the upper region may be formed with a same width or different widths.

The semiconductor device may further include: a first passivation layer on the barrier layer; a second passivation layer on the first passivation layer; and a third passivation layer on the second passivation layer. A field plate may be further formed on the third passivation layer.

The semiconductor device may further include a source contact plug and a drain contact plug in contact with the source metal and the drain metal, respectively. The source contact plug and the drain contact plug may be connected to a metal line through the first to third passivation layers.

In another general aspect, a semiconductor device includes: a substrate; a P-type gallium nitride (P-GaN) region on the substrate; a gate metal on the P-GaN region; and a source metal and a drain metal formed on left and right sides of the P-GaN region. The P-GaN region has a staircase shape and is formed in either symmetric or asymmetric shape.

The P-GaN region may be formed to extend further in a direction towards the drain metal.

The P-GaN region may have a greater number of steps in the direction towards the drain metal.

A length of the left and right sides of the P-GaN region may be adjustable.

The gate metal may include an upper region and a lower region. The upper region and the lower region may be formed in a same pattern or in different patterns.

The semiconductor device may further include: a buffer layer on the substrate; a channel layer on the buffer layer; a barrier layer on the channel layer; first passivation layer, second passivation layer, and third passivation layer on the barrier layer; and a field plate on a portion of the third passivation layer.

Other features and aspects will be apparent from the following detailed description, the drawings, and the claims.

### BRIEF DESCRIPTION OF THE DRAWINGS

FIG. 1 illustrates a cross-sectional view of a GaN-based semiconductor device.

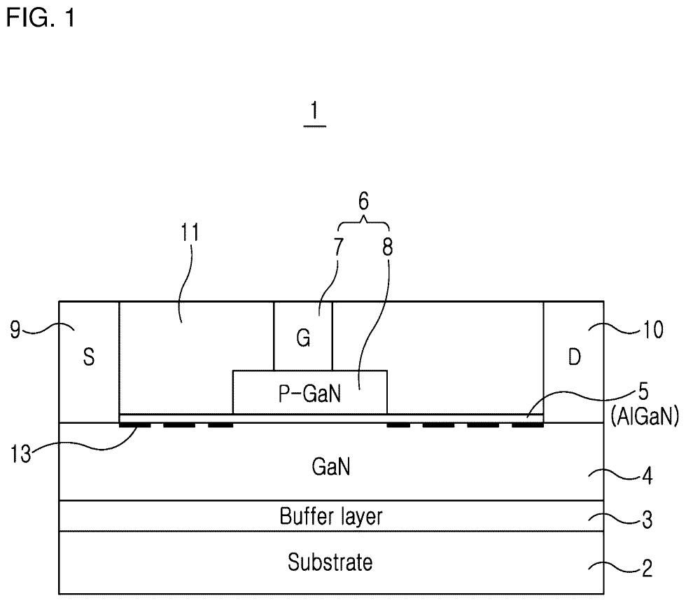

FIG. 2 illustrates a cross-sectional view of a high electron mobility transistor (HEMT) device according to an example of the present disclosure.

FIG. 3 illustrates a top view of a gate metal and a P-GaN region according to an example of the present disclosure, along with a cross-sectional view taken along line A-A′.

FIG. 4 illustrates a top view of a gate metal according to another example of the present disclosure.

FIG. 5 illustrates cross-sectional views taken along lines A-A′, B-B′, and C-C′ in the top view of the gate metal in FIG. 4.

FIG. 6 illustrates a top view of a gate metal according to another example of the present disclosure.

FIG. 7 illustrates cross-sectional views taken along lines A-A′, B-B′, and C-C′ in the top view of the gate metal in FIG. 6.

FIG. 8 illustrates a top view of a gate metal according to another example of the present disclosure.

FIG. 9 illustrates cross-sectional views taken along lines A-A′ and B-B′ in the top view of the gate metal in FIG. 8.

FIG. 10 illustrates a top view of a gate metal according to another example of the present disclosure, along with a cross-sectional view taken along line A-A′.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

A detailed description is given below, with reference to attached drawings.

The present disclosure addresses the above problems and provides a high electron mobility transistor device having an improved structure of the P-GaN region and gate metal to minimize damage to the P-GaN due to leakage current.

The technical problems of the present disclosure are not limited to those mentioned above, and other technical problems not mentioned will be apparent to those skilled in the art from the following description.

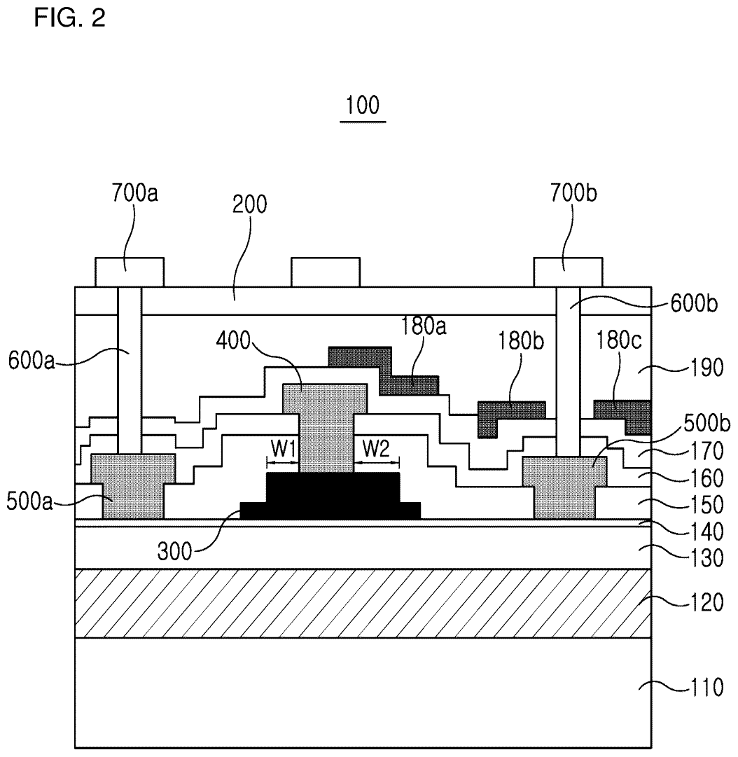

FIG. 2 illustrates a cross-sectional view of a high electron mobility transistor (HEMT) device according to an example of the present disclosure. In FIG. 2, the HEMT 100 may be an E-mode GaN (P-GaN) device that is in a normally OFF state, i.e., no channel is formed when no gate voltage is applied.

The HEMT device 100 according to the present disclosure includes a substrate 110, a buffer layer 120, a channel layer 130, and a barrier layer 140. The substrate 110 may be a silicon carbide substrate, a silicon substrate, or a sapphire substrate. The buffer layer 120 between the substrate 110 and the channel layer 130 may be aluminum nitride (AlN) or AlGaN. The buffer layer 120 may be formed by stacking two or more layers. The channel layer 130 includes channel regions in which conductive channels are selectively formed therein, and may be formed of GaN. The barrier layer 140 is formed adjacent to the top surface of the channel layer 130. The barrier layer 140 is formed of a thin film of AlGaN with a band gap larger than the band gap of the channel layer 130.

The HEMT device 100 includes a P-type GaN (P-GaN) region 300 on a barrier layer 140 where a gate region is to be formed, and a gate metal 400 formed on the P-GaN region 300. In this example, the P-GaN region 300 is formed in a staircase shape. When a bias voltage is applied to the gate, current flows downward through the gate metal 400, which allows current to flow through the surface of the P-GaN region 300. The device is damaged by the leakage current generated by this current flow, and forming the P-GaN region 300 in a staircase shape as described above has the advantage of minimizing the damage caused by the leakage current. The staircase shape of the P-GaN region 300 can adopt a variety of structures. This will be described with reference to various examples described below.

The stepped P-GaN region 300 may be formed in a symmetric or asymmetric structure, and when formed in an asymmetric shape, it is more effective in minimizing problems caused by leakage currents. For example, the P-GaN region 300 may have a first length W1 in the direction towards a source and a second length W2 in the direction towards a drain, centered on the gate metal 400, where the second length W2 may be formed to be longer than the first length W1 (W2>W1), as shown in FIG. 2. In this way, by securing a longer length in the P-GaN region 300 in the direction of the drain than in the direction of the source, more staircase structures can be formed, which can provide a leakage current reduction effect. Of course, the present disclosure is capable of adjusting the lengths of the first length W1 and the second length W2 differently to any extent, and the first length W1 and the second length W2 may also be formed the same so that the first length W1 and the second length W2 are symmetrical to each other.

The gate metal 400 is formed extending perpendicular to the top of the P-GaN region 300. The gate metal 400 is a conductive material, such as a metal, and includes titanium (Ti), nickel (Ni), aluminum (Al), and gold (Au). For example, the gate metal 400 may be a gate Schottky metal (GSM).

The HEMT device 100 includes a source metal 500a and a drain metal 500b. The source metal 500a and drain metal 500b are disposed at predetermined intervals to the left and right of the P-GaN region 300, respectively, and their bottoms are formed to be in contact with the barrier layer 140.

As shown in FIG. 2, the HEMT device 100 includes a first passivation layer 150, a second passivation layer 160, a third passivation layer 170, a field plate 180a/180b/180c, an interlayer insulating layer 190, and a capping layer 200.

The first passivation layer 150 is stacked along the surface of the barrier layer 140 and the P-GaN region 300. The second passivation layer 160 is stacked along the top surface of the first passivation layer 150. The third passivation layer 170 is stacked along the top surface of the second passivation layer 160. When the third passivation layer 170 is formed, the gate metal 400, the source metal 500a, and the drain metal 500b are all covered.

The first passivation layer 150 is used as a layer to protect the P-GaN region 300 and further reduce trap formation on the sides of the P-GaN region 300. The first passivation layer 150 may reduce leakage current in the HEMT device 100.

A field plate 180a, 180b, 180c is formed above the third passivation layer 170. The field plate 180a, 180b, 180c may be formed by a sputtering method using a material such as TiN, and includes first to third field plates 180a, 180b, 180c. The first field plate 180a is formed by partially overlapping the gate metal 400 and the P-GaN region 300 vertically and extending towards the drain metal 500b. The second and third field plates 180b, 180c are symmetrically formed at both ends of the drain metal 500b. These field plates 180b/180c can mitigate the electric fields concentrated in the gate region and the drain region.

The interlayer insulating layer 190 is formed with a predetermined thickness to cover both the third passivation layer 170 and the field plate 180. The interlayer insulating layer 190 may be formed of silicon oxide (SiO₂) or a material such as TEOS, BPSG, PSG, or the like. The capping layer 200 refers to TEOS formed using silicon oxide (SiO₂), for example, by a PECVD process.

Referring to FIG. 2, a contact plug 600 and a metal line 700 are formed. The contact plug 600a, 600b includes a source contact plug 600a in connection with the source metal 500a, and a drain contact plug 600b in connection with the drain metal 500b. The source contact plug 600a and the drain contact plug 600b are formed by penetrating the second passivation layer 160, the third passivation layer 170, the interlayer insulating layer 190, and the capping layer 200. The metal lines 700a, 700b are connected with the source contact plugs 600a and drain contact plugs 600b and are formed on top of the capping layer 200.

The present disclosure is to design the structure of the gate metal 400 and the P-GaN region 300 in various forms so that when a bias voltage is applied to the gate, the path of the current applied through the gate metal 400 and the P-GaN region 300 is formed as long as possible to alleviate the electric field, as will be described in detail with reference to the following exemplary drawings.

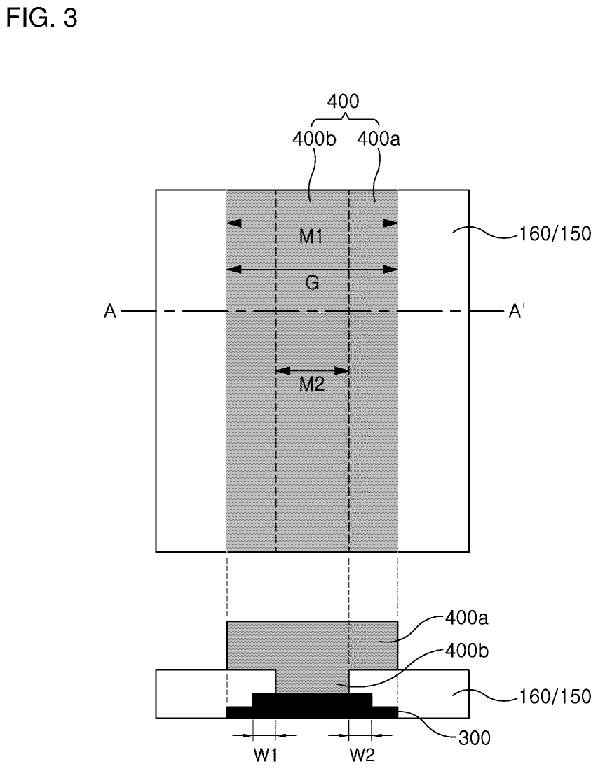

FIG. 3 illustrates a top view of a gate metal 400 and a P-GaN region 300, along with a cross-sectional view taken along line A-A′, according to an example of the present disclosure.

Referring to FIG. 3, a P-GaN region 300 and a gate metal 400 disposed on the P-GaN region 300 are shown. The P-GaN region 300 is formed in a stepped shape in the left and right directions. The shape of the steps can effectively disperse the electric field. The more steps formed in the staircase shape, the greater the current dispersion effect, and the more the electric field can be mitigated.

The gate metal 400 may be formed to include an upper region 400a of a first width M1 and a lower region 400b of a second width M2. The first width M1 of the upper region 400a is wider than the second width M2 of the lower region 400b. The bottom of the second lower region 400b is in direct contact with the top surface of the P-GaN region 300.

In FIG. 3, the first width M1 of the upper region 400a and the overall width G of the P-GaN region 300 may be formed to be the same. However, it is also possible to form the P-GaN region 300 by extending the left and right ends of the P-GaN region 300 to protrude further than the upper region 400a. In particular, if more space can be provided to form a staircase shape of the P-GaN region 300 towards the drain, more steps can be formed, which helps to disperse the electric field rather than concentrate it.

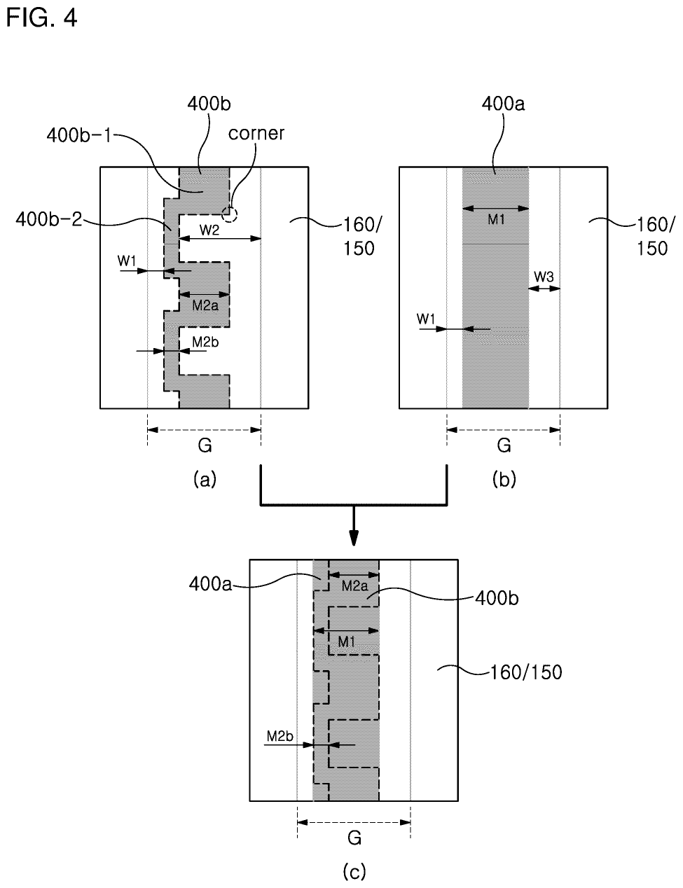

FIG. 4 illustrates a top view of a gate metal 400 according to another example of the present disclosure. In FIG. 4, the gate metal is shown separated into an upper region and a lower region, which are formed in different patterns.

FIG. 4 (a) illustrates a lower region 400b of the gate metal 400. As shown, the lower region 400b, which is disposed on top of the P-GaN region G, 300, is formed in a zigzag pattern shape and has different widths M2a, M2b. From a top view, the lower region 400b may include a first region 400b-1 and a second region 400b-2 having different areas. The first region 400b-1 is formed with a larger area than the second region 400b-2. Thus, the first region 400b-1 has an increased Schottky contact area and the second region 400b-2 has a decreased Schottky contact area. Depending on the Schottky contact area, the current performance varies.

A relative increase in Schottky contact area may result in an increase in current performance, meaning the amount of current, which may result in improved performance. Conversely, a decrease in Schottky contact area may be detrimental to current performance, but it may be advantageous to form a stepped P-GaN region 300 towards the drain metal 500b. This is because more space can be used to form the P-GaN region 300 towards the drain metal 500b. This Schottky contact area can be adjusted to any extent depending on the characteristics of the device to be fabricated.

As shown FIG. 4 (a), the second length W2 towards the drain may be formed longer than the first length W1 towards the source of the P-GaN region G (W1<W2).

In FIG. 4 (a), each corner portion of the lower region 400b is shown to be formed as rectangular. However, it is also possible to form each corner of the lower region 400b in a rounded shape. The ability to form the corners of the lower region 400b in a rounded shape is equally applicable to other examples described below.

FIG. 4 (b) illustrates an upper region 400a of the gate metal. As shown, the upper region 400a is formed with the same width throughout, and is disposed above the P-GaN region 300 so as to be slightly closer to the source. Thus, a third length W3 towards the drain is formed longer than a first length W1 towards the source of the P-GaN region 300 (W1<W3).

FIG. 4 (c) illustrates a top view of a gate metal 400 in a state in which the upper region 400a and the lower region 400b overlap. As shown, the lower region 400b is disposed below the upper region 400a of the gate metal 400, and the gate metal 400 is disposed slightly closer to the source in the P-GaN region 300 G. In this case, the upper region 400a is formed with the same width M1 throughout, while the lower region 400b is formed in a zigzag shape with different areas. More specifically, the lower region 400b may be formed with a portion equal to the width M1 of the upper region 400a and a portion having different widths M2a, M2b that are smaller than the width M1 of the upper region 400a.

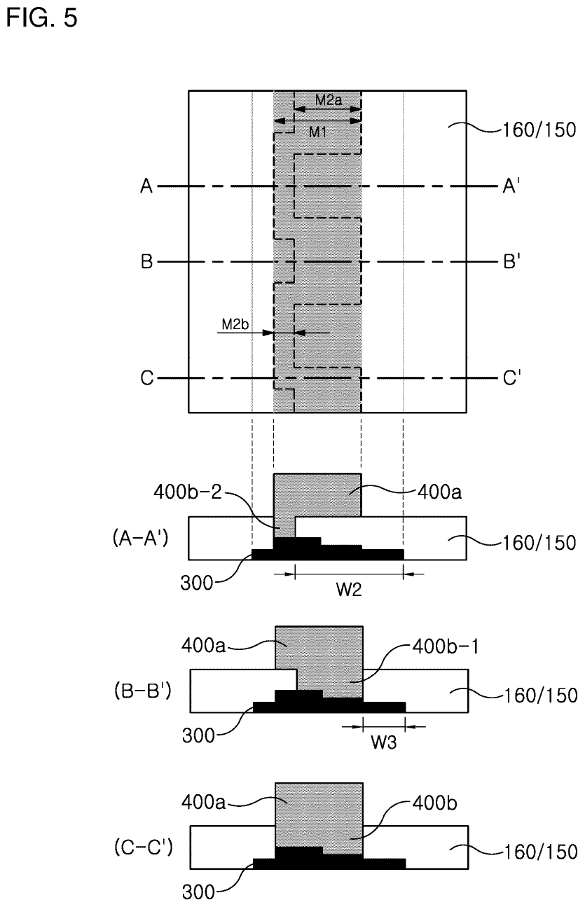

FIG. 5 illustrates cross-sectional views taken along lines A-A′, B-B′, and C-C′ in the top view of the gate metal in FIG. 4.

Referring to the cross-sectional view of line A-A′ in FIG. 5, a second region 400b-2, which has a smaller width, of the lower region 400b is in direct contact with the top of the step-shaped P-GaN region 300. The P-GaN region 300 can be elongated by W2 towards the drain, thereby providing a larger space for forming the P-GaN region 300 towards the drain. Thus, more steps can be formed in the elongated P-GaN region 300, and the electric field dispersion effect can be increased accordingly.

Referring to the cross-sectional view of line B-B′ in FIG. 5, a first region 400b-1, which has a greater width, of the lower region 400b is in direct contact with the top of the step-shaped P-GaN region 300. Even in this case, since the third length W3 towards the drain is formed longer than the first length W1 towards the source of the P-GaN region 300, it is possible to form a P-GaN region 300 in the shape of more steps. Since the wide first region 400b-1 is in direct contact with the top of the P-GaN region 300, the current performance can also be advantageous.

Referring to the cross-sectional view of line C-C′ in FIG. 5, both the first region 400b-1 and the second region 400b-2 constituting the lower region 400b of the gate metal are in contact with the top of the step-shaped P-GaN region 300. In this case, a P-GaN region 300 with more steps can also be formed.

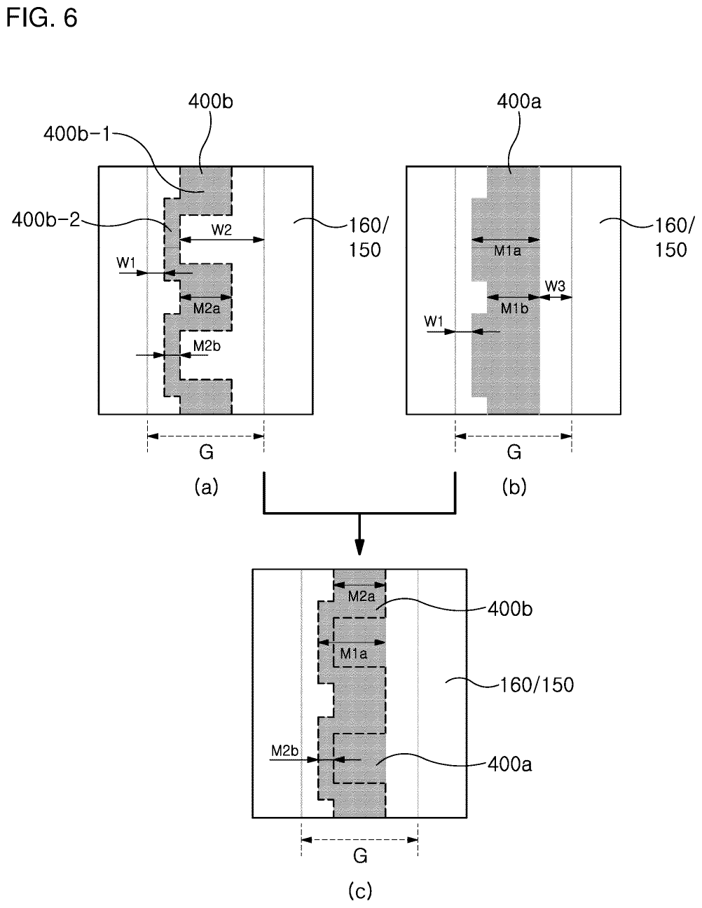

FIG. 6 illustrates a top view of a gate metal according to another example of the present disclosure. Similar to FIG. 4, the upper region 400a and the lower region 400b of the gate metal are formed in different patterns. Details are provided in the following.

FIG. 6 (a) illustrates a lower region 400b of the gate metal. The structure is the same as the structure of the lower region of the gate metal in FIG. 4 (a) described above. The lower region 400b, which is disposed on top of the P-GaN region G, is formed in a zigzag pattern shape and has different widths M2a, M2b. From the perspective of a top view, the lower region 400b may include a first region 400b-1 and a second region 400b-2 having different areas. The first region 400b-1 is formed with a larger area than the second region 400b-2. Thus, the first region 400b-1 has an increased Schottky contact area and the second region 400b-2 has a decreased Schottky contact area. Furthermore, as shown in FIG. 6 (a), a second length W2 towards the drain is formed longer than a first length W1 towards the source of the P-GaN region G (W1<W2).

FIG. 6 (b) illustrates an upper region 400a of the gate metal. As shown, the upper region 400a is formed with different widths M1a, M1b, and also has a third length W3 towards the drain longer than the first length W1 towards the source in the P-GaN region G (W1<W3).

FIG. 6 (c) illustrates a gate metal where the upper region and the lower region overlap. The lower region 400b is disposed below the upper region 400a. The upper region and the lower region are slightly closer to the source around the center of the P-GaN region G, and the P-GaN region G is further expanded towards the drain.

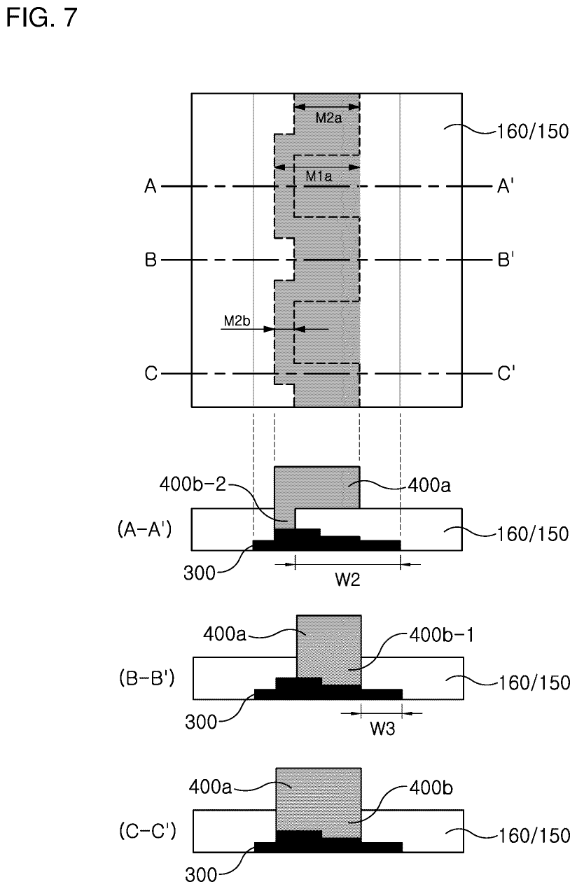

FIG. 7 illustrates cross-sectional views taken along lines A-A′, B-B′, and C-C′ in the top view of the gate metal in FIG. 6.

Referring to the cross-sectional view along line A-A′ in FIG. 7, a second region 400b-2, which has a smaller width, of the lower region 400b is in direct contact with the top of the step-shaped P-GaN region 300. The P-GaN region 300 is formed by extending the P-GaN region 300 towards the drain by a distance W2, so that a larger space is available for forming the P-GaN region 300 towards the drain. Therefore, it is advantageous to form more steps in the elongated P-GaN region 300, thereby increasing the electric field dispersion effect.

Referring to the cross-sectional view along line B-B′ in FIG. 7, a first region 400b-1, which has a greater width, of the lower region 400b is in direct contact with the top of the step-shaped P-GaN region 300. Similarly, a larger space is available to form the P-GaN region 300 towards the drain, which can be formed by adding a step shape towards the drain, and the Schottky contact area is increased because the first region 400b-1 is in contact with the step shape.

Referring to the cross-sectional view along line C-C′ in FIG. 7, both the first region 400b-1 and the second region 400b-2 constituting the lower region 400b are in contact with the top of the step-shaped P-GaN region 300.

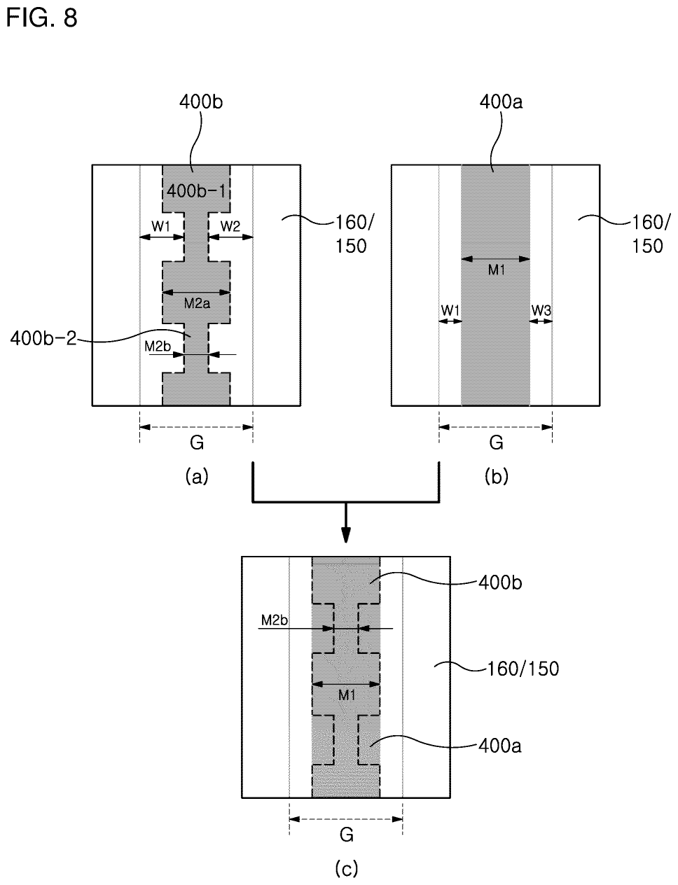

FIG. 8 illustrates a top view of a gate metal according to another example of the present disclosure. In FIG. 8, the upper and lower regions of the gate metal are formed in different patterns.

FIG. 8 (a) illustrates a lower region 400b of the gate metal. As shown, the lower region 400b disposed on the P-GaN region 300 may have a shape in which a first region 400b-1 with a large area and a second region 400b-2 with a relatively small area are disposed continuously. The first region 400b-1 may have a width of M2a, and the second region 400b-2 may have a width of M2b. The second region 400b-2 may be connected between the first regions 400b-1.

Due to the differently sized regions, the first region 400b-1 has an increased Schottky contact area, and the second region 400b-2 has a decreased Schottky contact area. As described above, if the Schottky contact area increases, current performance can be advantageous, and if the Schottky contact area decreases, the current performance decreases. Therefore, it is advantageous to form a step-shaped P-GaN region 300 towards the drain. Depending on the characteristics of the device, the Schottky contact area can be adjusted to any extent.

As shown in FIG. 8 (a), in the P-GaN region 300, the lower region 400b is centrally located such that the first length W1 towards the source and the second length W2 towards the drain are equal to each other (W1=W2).

FIG. 8 (b) illustrates an upper region 400a of the gate metal. As shown, the upper region 400a is formed with the same width and is disposed in the center of the P-GaN region G. Thus, the first length W1 towards the source and the third length W3 towards the drain are equal to each other in the P-GaN region G.

FIG. 8 (c) illustrates a gate metal in which the upper region 400a and the lower region 400b overlap. The lower region 400b is disposed below the upper region 400a. The total length of the first region 400b-1 and the second region 400b-2 of the lower region 400b is the same as the total length of the upper region 400a.

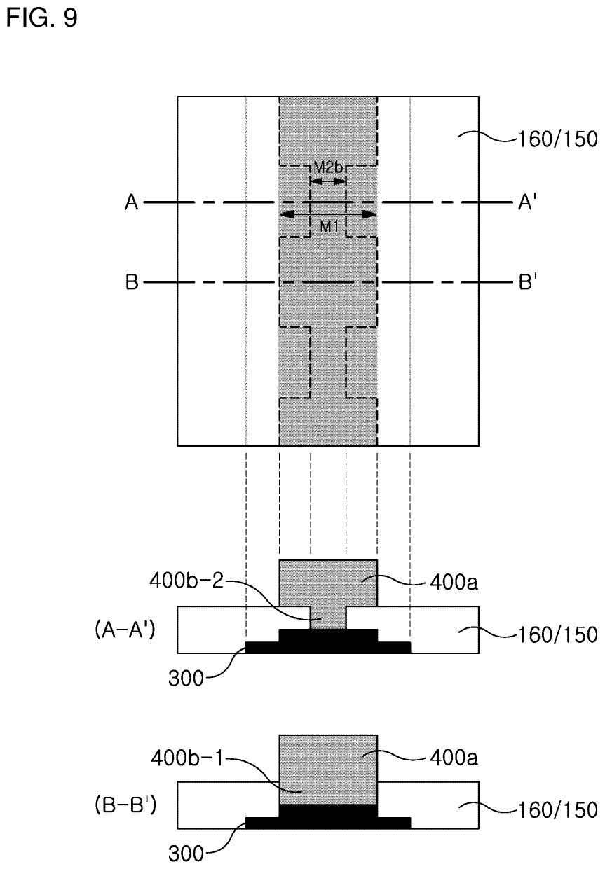

FIG. 9 illustrates cross-sectional views taken along lines A-A′ and B-B′ in the top view of the gate metal in FIG. 8.

Referring to the cross-sectional view along line A-A′ in FIG. 9, a second region 400b-2, which has a smaller width, of the lower region 400b is in direct contact with the center of the step-shaped P-GaN region 300. Because the width of the second region 400b-2 is small compared to the width of the top surface of the P-GaN region 300, only a portion of the top surface of the P-GaN region 300 is in contact with the second region 400b-2.

The P-GaN region 300 has a staircase shape that is symmetrical to each other in a source-side direction and a drain-side direction.

Referring to the cross-sectional view along line B-B′ in FIG. 9, a first region, which has a greater width, of the lower region 400b is in direct contact with the top of the P-GaN region. Since the width of the top surface of the P-GaN region 300 and the width of the first region 400b-1 are the same, the first region 400b-1 is in contact with the entire top surface of the P-GaN region 300.

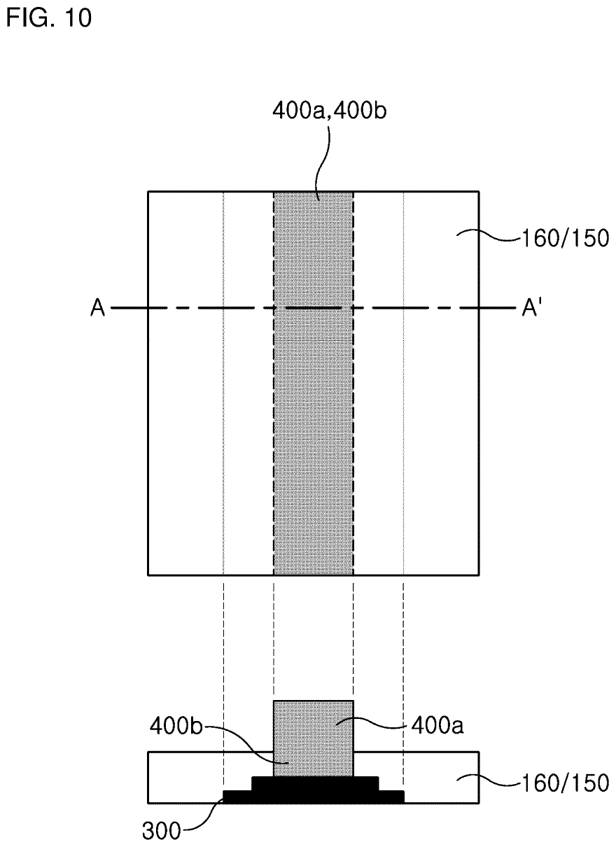

FIG. 10 illustrates a top view of a gate metal according to another example of the present disclosure, along with a cross-sectional view taken along line A-A′.

Referring to FIG. 10, the upper region 400a and the lower region 400b of the gate metal 400 have the same width. Therefore, compared to the previously described gate metal structure, the gate metal can be manufactured using a simpler process.

The gate metal 400 is disposed in the center of the step-shaped P-GaN region 300, such that the P-GaN region 300 has a first length W1 towards the source and a third length W3 towards the drain.

As described above, it can be seen that the present disclosure proposes a structure that varies the placement and geometry of the P-GaN region and the gate metal disposed on top of the P-GaN region, which can be used to drive the E-Mode GaN Power HEMT device more reliably.

According to the present disclosure, various exemplary structures are proposed for the P-GaN region and the gate metal formed above the P-GaN region to form the sides of the the P-type gallium nitride (P-GaN) region in a shape of step and further to form a greater number of steps towards the drain. As a result, the electric field applied to the P-GaN region is dispersed, preventing damage to the device due to field concentration.

Therefore, the overall performance of the semiconductor device may be expected to be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device, comprising:
a substrate;
a buffer layer on the substrate;
a channel layer on the buffer layer;
a barrier layer on the channel layer;
a step-shaped P-type gallium nitride (P-GaN) region on the barrier layer;
a source metal and a drain metal formed on left and right sides of the P-GaN region; and
a gate metal on the step-shaped P-GaN region.

2. The semiconductor device of claim 1, wherein the step-shaped P-GaN region is formed to extend further in a direction towards the drain metal than in a direction towards the source metal.

3. The semiconductor device of claim 1, wherein the step-shaped P-GaN region has a greater number of step shapes in the direction towards the drain metal.

4. The semiconductor device of claim 1, wherein the gate metal comprises an upper region and a lower region,
wherein the upper region is formed with a first width, and
wherein the lower region is formed with the first width, and a second width and a third width smaller than the first width.

5. The semiconductor device of claim 4, wherein the step-shaped P-GaN region is not in contact with the lower region, and
wherein a first length formed towards the source metal is not in contact with the lower region and is shorter than a second length formed towards the drain metal.

6. The semiconductor device of claim 4, wherein the second width is smaller than the third width, and
wherein the second width is formed closer to the source metal.

7. The semiconductor device of claim 4, wherein in the lower region, a first region and a second region with different areas are formed in a zigzag pattern, and
wherein the upper region is formed with a same width or different widths.

8. The semiconductor device of claim 1, further comprising:
a first passivation layer on the barrier layer;
a second passivation layer on the first passivation layer; and
a third passivation layer on the second passivation layer,
wherein a field plate is further formed on the third passivation layer.

9. The semiconductor device of claim 8, further comprising:
a source contact plug and a drain contact plug in contact with the source metal and the drain metal, respectively,
wherein the source contact plug and the drain contact plug are connected to a metal line through the first to third passivation layers.

10. A semiconductor device, comprising:
a substrate;
a P-type gallium nitride (P-GaN) region on the substrate;
a gate metal on the P-GaN region; and
a source metal and a drain metal formed on left and right sides of the P-GaN region,
wherein the P-GaN region has a staircase shape and is formed in either symmetric or asymmetric shape.

11. The semiconductor device of claim 10, wherein the P-GaN region is formed to extend further in a direction towards the drain metal.

12. The semiconductor device of claim 11, wherein the P-GaN region has a greater number of steps in the direction towards the drain metal.

13. The semiconductor device of claim 10, wherein a length of the left and right sides of the P-GaN region is adjustable.

14. The semiconductor device of claim 10, wherein the gate metal comprises an upper region and a lower region, and
wherein the upper region and the lower region are formed in a same pattern or in different patterns.

15. The semiconductor device of claim 10, further comprising:
a buffer layer on the substrate;
a channel layer on the buffer layer;
a barrier layer on the channel layer;
first passivation layer, second passivation layer, and third passivation layer on the barrier layer; and
a field plate on a portion of the third passivation layer.
